(19) United States
(12) Patent Application Publication
(10) Pub. No.: US 2026/0282627 A1
(43) Pub. Date: Sep. 17, 2026

(54) OPTOELECTRONIC ARRANGEMENT AND METHOD FOR OPERATING THE SAME

(71) Applicant: AMS-OSRAM INTERNATIONAL GMBH, Regensburg (DE)

(72) Inventors: Norwin von Malm, Nittendorf (DE); Martin Hetzl, Painten (DE); Tansen Varghese, Regensburg (DE); PHILIPP Kreuter, Regensburg (DE)

(21) Appl. No.: 19/479,990

(22) PCT Filed: Apr. 30, 2024
(86) PCT No.: PCT/EP2024/061943

§ 371 Date: Oct. 29, 2025

(30) Foreign Application Priority Data
May 2, 2023 (DE) 10 2023 111 339.9

(51) Int. Cl. H10H 29/14; H10H 20/812

(52) U.S. Cl. CPC H10H 29/14; H10H 20/812

(57) ABSTRACT

In an embodiment an optoelectronic arrangement includes a plurality of optoelectronic components, each having a main emission surface attachable to one or more optical fibres, wherein each of the plurality of optoelectronic components includes a semiconductor layer stack, and wherein each semiconductor layer stack has a first layer having a first doping type, a second layer having a second doping type different from the first doping type and an active region arranged in between the first and second layer, the active region configured to emit light of a first wavelength, and a light source configured to emit light of a second wavelength, the second wavelength being shorter than the first wavelength, wherein the light source is configured to illuminate the active regions of each semiconductor layer stack to generate, by the active regions of each semiconductor layer stack, photoluminescent light.

### CROSS-REFERENCE TO RELATED APPLICATIONS

This patent application is a national phase filing under section 371 of PCT/EP2024/061943, filed Apr. 30, 2024, which claims the priority of German patent application no. 10 2023 111 339.9, filed May 2, 2023, each of which is incorporated herein by reference in its entirety.

### TECHNICAL FIELD

The present invention concerns an optoelectronic arrangement for optical data communication and a method for operating one or more optoelectronic components in an optical data communication arrangement, said one or more optoelectronic components attached to one or more optical fibres, the one or more optoelectronic components configured to be supplied individually by a voltage and/or current signal.

### BACKGROUND

The use of μLEDs for optical and data communication has several benefits. Apart from the small size, which provides an easier interconnect to optical fibres, the vertical optoelectronic components usually implemented as μLEDs provide an improved scalability and can be easily implemented in existing designs at large numbers. In this regard a μLED is an optoelectronic component that comprises a diameter or more general a dimension that is smaller than 50 μm and in particular smaller than 20 μm. In some special applications, a μLED can range in diameter between 2 μm and 10 μm.

μLEDs in comparison to conventional LEDs with larger sizes further require a very low current resulting in an overall low power consumption, thereby reducing the amount of heat generated during operation. This again not only saves power, which is particularly suitable for short and midrange interconnects, but also simplifies the requirements regarding the heat transfer layer enabling a dense application of such optoelectronic components. Hence arrays of such μLEDS have been proposed as source for optical data communication, in which light signals from several μLEDs are coupled into a multi optical fibre arrangement.

However, apart from the requirement of a high quantum efficiency to provide enough light, data communication also requires a high switchability or more general a large amplitude modulation depth at high frequencies. Current optical data communication ranges from several hundred Megahertz to a few Gigahertz, for example in the range between 10 GHz and 50 GHz.

As a result thereof, current μLEDs have to be switched on and off or at least modulated in their respective emission amplitude within that frequency range. Given the fact, that a light pulse in itself requires a certain length to be detected at the receiver end, such high frequencies require a radiative recombination lifetime in the range of a few ten picoseconds and less. The radiative recombination lifetime is the time required for the minority charge carriers to recombine under radiation after turning off the current through the μLEDs. Likewise, when turning on the μLED, the depletion region in the active region has to be populated with charge carriers, which subsequently recombine. This will cause a certain rise time for the light pulse to be emitted.

Various measures have been proposed to reduce the rise and fall times during a pulse or amplitude modulated emission, as current μLEDs are limited in this regard resulting in a switching time of only a few hundred megahertz and rise and fall times to 100 ps or more.

As an example, background doping in the quantum barriers of the respective optoelectronic components can be implemented in order to increase the charge carrier density. While this is suitable in some cases, it requires a precise control during the epitaxial growth of the quantum barriers. As an alternative, non-radiative defect centres within the active region can be provided to increase the non-radiative recombination competing with radiative recombination of the charge carrier. However, due to dopant or defect centre diffusion and other characteristics, those induced measures face reliability issues and are difficult to control during processing of the devices.

### SUMMARY

Embodiments provide optoelectronic devices or optoelectronic components having a higher switching speed in order to provide the improved rise and fall time for high speed optical data communication.

The inventor realized that a significant portion of the recombination time for charge carriers in the active region is given by the charge carrier injection and transport time through the doped layers and into the active region. All the minority carriers have to be removed from the active region of the μLED when switching the state of the μLED from “ON” to “OFF”. This is usually one by recombination of the minority carriers, either radiatively or non-radiatively. Likewise, any minority charge carriers have to diffuse through the respective doped layers of the μLED into the active region and populate it before recombining therein under the emission of light. Hence, the raise time as well as the fall time of a light pulse emitted by the μLED are significantly dependent on the time necessary to empty or populate the active region.

As a result thereof, the inventors propose to generate the respective minority carriers directly in the active region, thereby bypassing the diffusion of the charge carrier into the region during the forward bias of the μLED. Such approach is achieved by optically pumping the active region or active region of the μLED, such that charge carriers in form of electron-hole pairs are generated by absorption of excitation light (with light having a slightly larger energy than the bandgap of the active region) in the active region. The charge carriers are then recombining again after a short time under emission of light, whereas the wavelength now follows the energy of the bandgap.

In order to switch the μLEDs from the “ON” state to the “OFF” state, a reverse bias voltage signal is applied to the active region, depleting the induced and generated charge carriers (i.e. separating the electron hole pairs, so they can no longer recombine). In other words, a reversed electrical field is applied separating the induced charge carriers spatially thereby preventing them from recombination. This causes a modulation of the generation of photoluminescence, due to separating the charge carriers.

The proposed principle results in a significantly higher switching speed, because the charge carrier injection and transport time from the contact or the doped layers into the active region as mentioned above is neglected and not applicable. The optical pumping causes charge carriers are to be present in the active region. Switching the respective μLED “ON” and “OFF”, that is enabling or disabling the radiative recombination of the induced charge carriers (that is the generation of photoluminescence) is realized by an electric field instead of carrier injection by a current

Consequently, depletion can be easily achieved by application of a reverse bias signal to the μLED, whereas populating the active region is achieved by simply switching off the reversed bias during the illumination of the active region by the excitation or pump light. It is possible in this regard to switch the μLED not only between OV and the revers bias, but actually between a small forward voltage (smaller than the threshold voltage of the active region) and the reverse signal. A small forward bias will support the transition from the “OFF” state to the “ON” state further reducing the rise time (i.e. increasing the speed). The small forward bias can be reduced, once the μLED is in the “ON” state.

In this regard, it might further be suitable to provide a filter in front of an optical fibre to prevent pump light from entering the optical fibre. However, such solution is not necessary if the optical fibre itself is selective in favour of the emitted light from the active region and not the pump light or a detector on the other side of the optical fibre is wavelength selective.

In some aspects, the inventors therefore propose an optoelectronic arrangement for optical data communication. The optoelectronic arrangement comprises a plurality of optoelectronic components. Each of the optoelectronic components, which can be implemented as a μLED, comprises a main emission surface that is attachable to one or more optical fibres. In this regard, the one or more optical fibres can comprise a multicore fibre optic arrangement. The optoelectronic components further each comprise a semiconductor layer stack, which is configured to be supplied individually by a voltage or a current signal.

The term “μLED” relates to an optoelectronic component that comprises a diameter of length smaller than 50 μm, and for example in the range of 2 μm to approximately 20 μm. μLEDs can be implemented as vertical or as horizontal μLED or optoelectronic components. In this regard, a “vertical optoelectronic component” or vertical μLED comprises two contact area arranged on opposite sides of each other, whereas one contact area may also for the main emission surface of the respective optoelectronic component and μLED. A horizontal optoelectronic component or horizontal μLED refers to a component or μLED that comprises the contact areas on the same side and preferably opposite the main emission surface. Furthermore and although not explicitly mentioned, a “surface emitter” is an optoelectronic component emitting its light substantially through a main emission surface. A so-called volume emitter in contrast thereto emits the light over its whole volume. The present application mainly refers to surface emitter, although the proposed principle is not limited to such type of emitter but can be also realized using volume emitters.

In accordance with the proposed principle, each semiconductor layer stack comprises a first doped layer having a first doping type, a second doped layer having a second doping type different from the first doping type and an active region arranged in between the first and second doped layer. The active region is also configured to emit light of the first wavelength.

In some aspects, the doped layer can comprise a plurality of sub-layers. For example in some aspects, the doped layers may comprise charge carrier blocking layers to prevent the charge carriers being induce by optical pumping form diffusing out of the active region. In some other aspects, the doped layers may comprise undoped cladding layers directly adjacent to the active region. The undoped cladding layers prevent an undesired diffusion of dopants into the active region.

In accordance with the proposed principle, the optoelectronic arrangement comprises a light source that is configured to emit excitation light having a second wavelength. The second wavelength is shorter than the first wavelength. The light source is configured and arranged to illuminate the active regions of each of the semiconductor layer stacks of the plurality of optoelectronic components. Illuminating the semiconductor layer stacks causes the generation of photoluminescent light by the active regions of each of the layer stacks, which is directed at least partially towards the main emission surface.

Hence, in accordance with the proposed principle, the optoelectronic components are not actively driven by a current to generate light, but illuminated by an excitation light source providing a pump light. The pump light is absorbed by the active region of the semiconductor layer stacks of the plurality of optoelectronic components generating charge carriers in form of electron-hole pairs in the active regions. The minority charge carriers are recombining in the active region under generation of photoluminescent light of the first wavelength, which is partially directed towards the main emission surface and subsequently collected by the optical fibres attached thereto.

The optoelectronic arrangement is now configured to modulate the generation of the photoluminescent light by respective supply signals for the plurality of optoelectronic components. Applying a reversed bias signal to the optoelectronic components that is providing a reversed voltage individually to the optoelectronic components, the components can be switched “OFF” and “ON”, thereby modulating the photoluminescent light signal having the first wavelength.

In other words, the excitation light is not modulated itself, but the generation of photoluminescent light through signals at the optoelectronic components and the semiconductor layer stacks thereof. The switching speed that is providing a reversed voltage is significantly higher with steep rise and fall times compared to the charge recombination time in conventional devices and may be limited either by the charge carrier recombination time or the switching time itself (that is by the driver circuit). Consequently, the switching speed is significantly improved and achieves raise and fall times in the range of a few picoseconds.

In some aspects, the supply voltage or current supply signals are configured to provide a reverse bias to the respective semiconductor layer stacks individually. Consequently, the light source can be configured to illuminate a plurality of those optoelectronic components at once, whereas the modulation occurs by individually providing a reverse bias signal to the respective semiconductor layer stacks. Hence, a plurality of such optoelectronic components can be individually addressed and switched in accordance with the data to be transferred by the optical data communication.

Some aspects concern the implementation of the plurality of optoelectronic components. In some aspects, the optoelectronic components are electrically attached to a common substrate. The common substrate comprises one or more control and driver circuits, which are configured to provide the voltage and/or current signal to individually supply the semiconductor layer stacks of the plurality of optoelectronic components, and more particularly to apply a reverse voltage or current signal thereto to deplete the charge carriers injected into the active region during illumination.

In some aspects, the one or more control and driver circuits can be configured to switch off the light source during data communication in cases the plurality of optoelectronic components are switched off as well. This will further reduce the power consumption and prevent an accidental and undesired detection of residual light either from the light source or a portion of the excitation light not being prevented by the reverse bias voltage. In some aspects in this reg, several light sources can be provided each light source being associated with a plurality of optoelectronic components. Hence, the arrangement may comprise an array of optoelectronic components and several light sources, wherein a light source is associated with a subset of the array of optoelectronic components. This will allow operating subsets of the array thereby reducing the overall power consumption. Blocking structured can be provided to separate the subsets in order to avoid undesired illumination.

Some aspects relate to the plurality of optoelectronic components. In some aspects, the components are realized as individual components, which are separately placed on the common substrate. In other aspects, the plurality of optoelectronic components are arranged as an array or monolithically integrated and may comprise a common contact plane for applying a common potential to the individual optoelectronic components. The common contact plane can be a transparent conductive contact plane and further comprises the main emission surfaces of the plurality of optoelectronic components. A transparent conductive contact plane may include a transparent conductive oxide like ITO for example. This will enable processing a plurality of optoelectronic components in a common device array with a plurality of components arranged in rows and columns and substantially isolated from each other. The main emission surface is formed by a transparent conductive contact as a common contact for each of the individually addressable components.

In this regard, the light source can be formed in between adjacent optoelectronic components also sharing the common contact plane as supply for common potential.

In some aspects, a reflector may be provided between adjacent optoelectronic components configured to reflect light of the first wavelength towards the main emission surface. In some aspects, the reflector is directly attached on the semiconductor layer stack as a reflective mirror for example. In a further embodiment, a reflector can be configured to reflect light of the second wavelength towards the active region of the plurality of optoelectronic components. Such reflector will further improve the efficiency of the excitation light by reflecting the excitation light towards the active region for generating the electron-hole pairs in the active region.

In this regard, the semiconductor layer stacks of the plurality of optoelectronic components may be embedded in a common insulation layer material, particularly a common insulation layer material that is at least partially transparent for the second wavelength. The common insulation layer material protects the optoelectronic components from potential damages or environmental impacts.

In some further aspects, the optoelectronic arrangement comprises one or more reflective elements arranged between two adjacent semiconductor layer stacks of the plurality of optoelectronic components within the common insulation layer material. Said one or more reflective elements are configured to redirect light of the second wavelength towards the semiconductor layer stacks and in particularly the active region thereof.

The active region of each of the semiconductor layer stacks may comprise a quantum well structure or a multi-quantum well structure. Both structures can be implemented with one or more doped quantum well layers and/or with one or more doped barrier layers. The doping in the quantum well layers as well as in the barrier layers will increase the charge carrier density and improve the speed during carrier recombination, thereby further improving the switching speed. In some aspects, the semiconductor layer stack may comprise a plurality of quantum dots.

In some further aspects, the semiconductor layer stack can comprise a mesa-etched structure, which is optionally suited to couple light of the second wavelength into the active region to further improve the quantum efficiency. It may be useful that the active region material comprises a larger bandgap adjacent to its perimeter of the mesa-etched structure and the mesa facets, respectively. A larger bandgap is for example implemented by using quantum well intermixing during the manufacturing process. As an alternative, the mesa-etched structure is covered by a regrowth layer that comprises a larger bandgap, resulting in a band-bending of the active region material adjacent to its perimeter. In both cases, an electrical potential within the active region is generated trapping the charge carriers within the central portion and keeping those away from the outer perimeter, thereby improving the quantum efficiency during optical pumping.

Some further aspects concern the arrangement and implementation of the light source. In some aspects, the light source comprises at least two optoelectronic devices, which are configured to illuminate the active region of the plurality of optoelectronic components from different locations. In some aspects, the at least two optoelectronic devices are configured to emit light from different directions and particularly directions not in the direction of the one or more optical fibres. In other words, the at least two optoelectronic devices corresponding to the light source may illuminate the plurality of optoelectronic components from the top that is towards the main emission surface of such components and not from their respective back sides. Such approach is useful to prevent excitation light from coupling into the optical fibres. In this regard, the in-coupling of the excitation light through the main emission surface into the active region can be improved by structuring or roughening the surface accordingly.

In some aspects, the optoelectronic arrangement comprises a filter, which is arranged downstream of the beam path of the main emission surface of the plurality of optoelectronic components. The filter is substantially transparent for light of the first wavelength and reflective or absorbent for light of second wavelength. The filter may be arranged in front of the one or more optical fibres to prevent light from the light source coupling into the optical fibres. Said filter can comprise a DBR mirror for example.

In some aspects, the light source comprises a semiconductor layer stack having an active region arranged laterally between the plurality of optoelectronic components and the one or more optical fibres. This semiconductor layer stack can cover plurality of optoelectronic components and act as a common semiconductor layer stack for the pump light for each of the optoelectronic components. The above-mentioned respective filter can be implemented as a DBR mirror arranged between the semiconductor layer stack of the light source and the one or more optical fibres. Depending on the geometry and the arrangement of the one or more optoelectronic components, the semiconductor layer stack can be interrupted between the optoelectronic components, such that the layer stack substantially emits light directly in front of the optoelectronic components, thereby further improving the efficiency. When the interrupted layer stack is further individually addressable, the plurality of optoelectronic components can be grouped together to be switched of such groups at once by simply turning off the pump light.

Alternatively, if the semiconductor layer stack of the plurality of optoelectronic components is configured to emit light over its whole surface, reflective elements can be arranged in between and adjacent to the optoelectronic components on the common substrate.

In some aspects, the semiconductor layer stack of the light source and each semiconductor layer stack of the plurality of optoelectronic components can share common contact plane. The common contact plane comprises a conductive transparent material, for example a conductive transparent oxide like ITO and acts as a common contact for supplying a ground or reference potential.

The semiconductor layer stack of the light source can comprise an active region including a quantum well structure or a multi-quantum well structure. The material of the light source may for example include Gallium Nitride, GaN or Gallium Phosphide, GaP as well as ternary and quaternary systems based on GaN and GaP, respectively, including but not limited to InGaN, InGaP and AlInGaN and AlGaInP. In this regard, the optoelectronic components can comprise similar material systems with the difference that its bandgap is smaller, thus emitting light with a longer wavelength. However, if the light source and the optoelectronic components are manufactured differently and separately a common contact plane or also a transparent oxide or any other suitable way can be selected to bond the semiconductor layer stack of the light source to the common contact plane of the plurality of optoelectronic components. Such bonding a can be implemented by transparent glue, or a transparent conductive oxide material as mentioned above.

In some aspects, the semiconductor layer stack of the light source may comprise one of materials above, while the material of the semiconductor layer stack of the plurality of optoelectronic components is based on a material system using GaAs, AlGaAs or combination thereof. It is possible to also implement the light source in such materials, like AlGaAs, however in case of the latter with different and higher Al content to provide light with more energy. Consequently, some aspects, the light source can emit red light, while the layer stack of the plurality of optoelectronic components is configured to emit light in the infrared spectrum.

In some further aspects, the control circuit is configured to provide a pulse or amplitude modulated reverse voltage to the plurality of optoelectronic components. The rise and fall time of such pulse modulated signal may be in the range of a few picoseconds, which is sufficient and can be directly transformed to corresponding rise and fall times of the light pulses of the plurality of optoelectronic components.

Another aspect is related to a method for operating one or more optoelectronic components in an optical or data communication system. The one or more optoelectronic components are attached to one or more optical fibres and configured to be supplied and driven individually by a voltage and/or current signal. The one or more optoelectronic components further comprise a semiconductor layer stack with an active region configured to emit light of a first wavelength.

In accordance with the proposed principle, the active regions of the layer stack of the one or more optoelectronic components are illuminated with light of a second wavelength, wherein said second wavelength is shorter than the first wavelength. This light is absorbed by the active region of the semiconductor layer stacks and generate charge carrier or electron hole pairs, which are usually recombining under generation of photoluminescence. Consequently, photoluminescence is generated in the active regions of the layer stack in response to illuminating the active region, with at least a portion of the photoluminescent light directed to one or more of the optical fibres.

A modulated reversed electrical field is applied at the active regions of the layer stacks for modulating the generation of photoluminescent light and thus implementing a modulated optical signal for data communication. Hence, the modulation is switched off by the reverse electrical field due to separation of the induced charge carrier by illumination. Portions of the modulated food photoluminescent light is then coupled into the one or more optical fibres.

The modulation does not occur directly by modulating the current through the optoelectronic component and μLEDs, but by modulating the generation of photoluminescence. This is achieved by reducing or enabling the recombination of optically induced charge carriers within the active region. In some aspects, the modulated electrical field is caused by individually applying a reversely biased voltage and/current signal to the one or more optoelectronic components.

In some aspects, the step of illuminating the active regions can comprise illuminating the active regions from different locations and or different directions and particularly not in the direction of the one or more optical fibres. This may improve the overall quantum efficiency and overall amount of photoluminescent light.

In this regard, light of the second wavelengths, which is reflected towards the beam path of the one or more optical fibres may be suppressed or absorbed for instance by a respective filter applied in front of the optical fibres. Such filter may include a wavelength selective DBR mirror. In some aspects, the optical fibres are adjusted to prevent in coupling of light of the second wavelength.

The proposed principle can be used in a system for optical data communication with a switching speed in the range of a plurality of 10 GHz or more with a rise and fall times of the signal pulses between 1 ps and 50 picoseconds and particularly below 30 ps.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows an embodiment of an optical arrangement in accordance with some aspects of the proposed principle;

FIG. 2 illustrates a second embodiment of an optoelectronic arrangement in accordance with some aspects of the proposed principle;

FIG. 3 shows a third embodiment of an optoelectronic arrangement in accordance with some aspects of the proposed principle;

FIG. 4 shows a fourth embodiment of an optoelectronic arrangement in accordance with some aspects of the proposed principle;

FIG. 5 illustrates a fifth embodiment of an optoelectronic arrangement in accordance with some aspects of the proposed principle;

FIG. 6 illustrates a sixth embodiment of an optoelectronic arrangement in accordance with some aspects of the proposed principle; and

FIG. 7 shows an embodiment of an optoelectronic component used for an optoelectronic arrangement in accordance with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

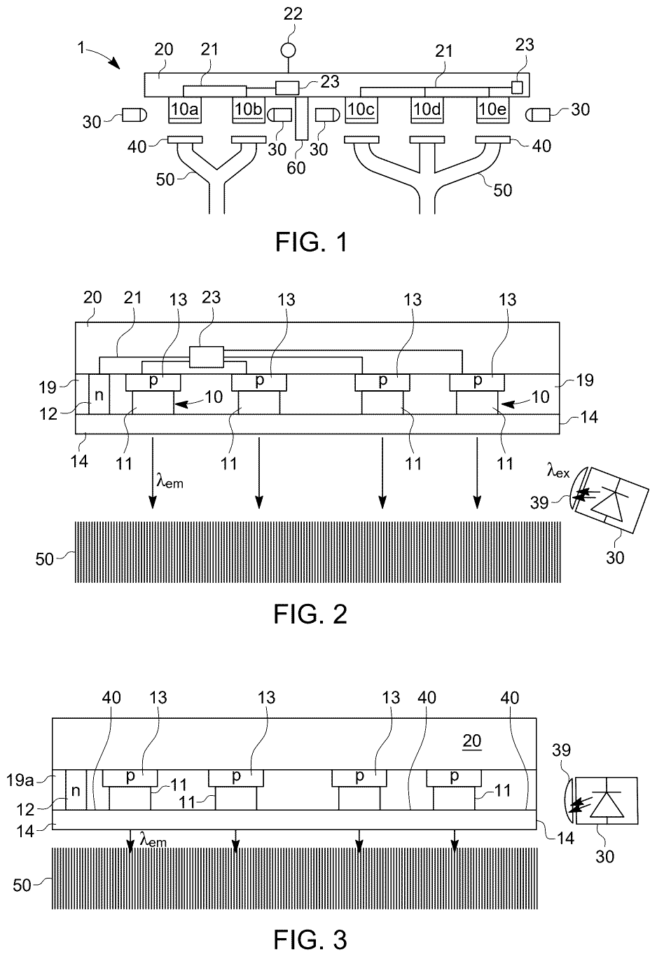

FIG. 1 illustrates a system for optical data communication using two arrangements in accordance with the proposed principle. The system for optical data communication is arranged on the PCB board, a mainboard and the like and attaches a plurality of optical fibres 50 implemented as a multicore fibre system to a plurality of outputs of optoelectronic components forming parts of the two optoelectronic arrangements.

More particularly, a plurality of optoelectronic components 10a, 10b to 10e is arranged separately on a substrate 20.

The optoelectronic components 10a to 10e are arranged in rows and columns and form substantially an array, which is divided into several sub-groups or sub-arrays, that are separated by an element 60. More particularly, a first sub-group is formed using optoelectronic components 10a and 10b, whereas the second sub-group of the array is implemented by the electronic components 10c, 10d and 10e, respectively. The substrate 20 includes several signals and supply lines 21 connected to control and driver circuits 23. Each subgroup of the array of optoelectronic components is connected via a supply line 21 to a respective control circuit 23 for individually addressing and supplying the respective optoelectronic components of each sub-group.

In the present embodiment, the optoelectronic components of 10a to 10e are implemented as horizontal μLEDs having their respective contact areas on the main surface opposite their emission surface. The μLEDs are implemented as surface emitters with their emission surface facing the optical fibres 50. The optoelectronic components 10a to 10e are connected by a solder material (not shown herein) with their contact areas to respective areas on the surface of the substrate 20. The contact areas on substrate 20 ae connected via supply traces to the control circuits 23, such that the optoelectronic components of each sub-group are supplied and controlled by one of the control and driver circuits 23.

Substrate 20 also comprises a data input connector 22 for providing a plurality of data signals to the respective control and driver circuits 23 of each sub-group. Data signals applied to the data input are digital signals consisting of “0” and “1” corresponding to a “HIGH” and “LOW” (or vice versa) for the optical signals, respectively. Data modulation, convolution and other aspects are usually well known. For simplicity in this application it is assumed that the any bit of data to be transmitted via the optical data communication system in FIG. 1 corresponds to a pulse of a certain length. Nevertheless, one will understand that the proposed principle is not limited to such concept, but more flexible. In particular PWM Signal modulation as well as wavelength multiplexing or other more complex modulation models are feasible herein.

Each sub-group further comprises a plurality of light sources 30 arranged adjacent to the plurality of optoelectronic components in each sub array to provide a light substantially parallel to the optical fibres 50. The light sources 30 are configured to illuminate the respective optoelectronic components and more particularly, the active region of the optoelectronic components 10a to 10e in each sub-group with an excitation light. For this purpose, the light sources 30 of each sub-group are embedded in a transparent insulation layer with a reflective material on the surface towards the optical fibres 50. Optical element in front of the light may collimate the excitation light to reduce the amount of excitation light into the optical fibres 50.

Furthermore, the plurality of light sources 30 in each sub-group are distributed in each sub-group to ensure an equal illumination of each of the optoelectronic components with excitation light, such that the resulting photoluminescence in the components is substantially equal.

Each of the optoelectronic components 10a to 10e is arranged with its emission surface close to an input of an optical fibre in front of a filter 40, which also acts as the input connector for the multicore fibre 50 attached thereto. Filter 40 is configured to absorb or reflect the excitation light, while being transparent to the photoluminescent light of the optoelectronic components 10a to 10e.

In operation of the data communication system, the light sources 30 in the sub-groups required for optical data communication are switched on continuously providing excitation light of a certain intensity towards the respective optoelectronic components 10a, 10b and 10c to 10e. Element 60 is blocking excitation light between the different sub-groups of the array and reflecting it back into the respective sub-group for further improving the efficiency. Furthermore, the solution indicated in FIG. 1 allows to individually switch off complete sub-groups of optoelectronic components at once by switching off the light sources 30 in the respective sub-group, providing a high flexibility and response to the volume of data to be transmitted.

The wavelength of the excitation light provided by light sources 30 comprises a wavelength, which is shorter than the wavelengths of the photoluminescent light generated in the active region of the optoelectronic components 10a and 10b as well as 10c to 10e, as the absorption efficiency of semiconductor material is dependent on the energy of the excitation light (to high energy photons may lead to multiple hole-pair generation, absorption in other areas of the components 10 and so forth), the wavelength of the excitation light of the light sources 30 is adjusted accordingly to match the various requirements. Usually the energy of the excitation light is higher than the energy difference of the bandgap, but not too high to prevent unnecessary heating of the optoelectronic components as well.

The excitation light is absorbed within the active region of the optoelectronic components and the layer stacks thereof and generates charge carriers in form of electron-hole pairs. These electron-hole pairs usually recombine radiatively under the generation of the photoluminescent light, whereas the photoluminescent light comprises a wavelength corresponding to the band gap energy (in first order approximation). The resulting photoluminescent light is emitted at least partially through the main emission surface and collected by the multicore fibre optics 50 attached thereto.

In accordance with the proposed principle, control driver circuits 23 are configured to causes a modulation of the generation of photoluminescent light in the respective optoelectronic components. This is achieved by providing a reverse bias generated by the driver and control circuits in response to the data to be transmitted individually to the optoelectronic devices via the supply traces 21. The reversed bias, e.g. a reverse voltage signal, causes the generation of an electric field within the active region that is reversed to the forward direction of the active region in the optoelectronic components.

As a result, the charge carriers generated by the incident excitation light from light sources 30 are spatially separated and removed from the active region by the electrical field provided by the driver and control circuits 23. Applying now a voltage and/or current signal to each of the optoelectronic components between 0 voltage and a reverse bias voltage causes a modulation of the generation of photoluminescent light, with 0 volt corresponding to photoluminescent light being generated and the reverse bias voltage corresponding to the generation of photoluminescent light being supressed. The overall modulation frequency of the photoluminescent light is substantially dependent on the carrier recombination lifetime within the active region as well as the switching speed provided by the driver and control circuits 23.

Consequently, in contrast to conventional solutions no charge carriers have to be injected into the active region or depleted therefrom during normal operation of the optoelectronic components. Rather, the charge carriers are generated continuously by the incident excitation light from light sources 30 and are either separated by an applied reverse electrical field or recombining again under the generation of photoluminescent light.

In this regard it is noted that zero voltage for the generation of photoluminescent light is only one possible solution. In fact, the driver and control circuit can be configured to switch between the reverse voltage for suppressing the generation of photoluminescent light and a small forward voltage, smaller than the threshold voltage. Apart from benefits in the implementation of the driver and control circuit, the approach may shorten the recombination lifetime or increase the charge carrier density within the active region improving the switching speed and increase the intensity of the photoluminescent light.

The optoelectronic components for an optoelectronic arrangement in accordance with the proposed principle are implemented with a slightly different layer stack compared to conventional μLEDs, which require carrier injection sub layers, a plurality of doped layers as well as the actual active regions. More particularly, the active regions in the semiconductor layer stacks of the optoelectronic components in accordance with the proposed principle can be optimized for absorbing incident excitation light with the excitation wavelength being shorter than the wavelength of the photoluminescent light. However, the material system, the processing parameters and the structure of the active region of the layer stacks can be adjusted to the excitation light (and vice versa as stated above) such that an absorption efficiency is maximized to improve the generation of photoluminescent light without depositing the additional energy in the crystal lattice, thereby heating up the active region.

In the embodiment of FIG. 1, the plurality of optoelectronic components 10a to 10e is implemented with separated semiconductor layer stacks, which are subsequently placed and soldered to the contact areas of substrate 20. However, in some aspects, the optoelectronic components as well as the layer stacks thereof can be implemented as a vertical components with a common contact on one side, for example, corresponding to the main emission surface. The layer stacks can again be implemented as separate optoelectronic components being transferred to the substrate 20 and placed on the contact areas thereof, but also implemented as a monolithically integrated structure. The latter enables the semiconductor layer stacks of the optoelectronic components to be optimized and directly arranged in rows and columns for being attached to a multicore fibre optics.

FIG. 2 illustrates a further embodiment, in which the optoelectronic components are implemented as a vertical components with a common transparent contact forming the main emission surface thereof. In this regard, the doping types of the contacts can be reversed, so the embodiment is not limited to the specific embodiment.

Substrate 20 comprises driver and control circuitry 23, which is connected to respective contact areas 13 forming p-contacts for semiconductor layer stacks 11 of the optoelectronic components 10. The layer stacks 11 include doped layers for carrier transport in case of modulating the supply voltage thereto, as well as an active region in between. The layer stack 11 of each of the optoelectronic components is embedded in a dielectric material 19. The main surface opposite the p-contacts 13 act as main emission surface and is covered by a transparent conductive common n-contact.

The common n-contact 14 is connected to one or more conductive and doped material 12, which is filled into a via through the insulating material 19. The material 12 is connected to another conductive trace line 21 within substrate 20. Common n-contact 14 comprises a transparent conductive oxide like ITO for example, which can further be structured or roughened to improve the out-coupling of the photoluminescent light with wavelength Nem to the multicore fibre 50. A light source 30 is arranged next to the plurality of optoelectronic components 10 providing an excitation light with wavelength Nex. Light source 30 may further include a lens or other optical elements 31 to collimate the light and focus the illumination onto the main emission surface of the respective optoelectronic components.

Similar to the previous embodiment, the incident excitation light with the excitation wavelength is absorbed in the active region of the layer stacks 11 of the plurality of optoelectronic components. By providing a reverse bias voltage signal separately and individually to each of the optoelectronic components and the layer stacks, the generation of photoluminescence is modulated, resulting in a pulse modulated optical signal that is fed into the multicore fibre 50.

FIG. 3 illustrates a further embodiment in accordance with the proposed principle. The insulating material 19a is transparent in this embodiment for the excitation light emitted by light source 30 and collimated by the optical arrangement 31. Light source 30 is arranged in such way that excitation light is substantially emitted in parallel to the common n-contact 14. In contrast to the previous embodiment, the exciting eliminating light is emitted substantially side-ways towards the respective layer stacks and not from the main emission surface. Due to the refractive index different, the small wangle between the excitation light and the n-contact, total reflection is achieved, such that material 19a acts as a light guide for the excitation light.

In addition or as a further alternative, a reflective mirror 40 can be provided between the common n-contact and the insulating material 19a. The reflective mirror for example a thin metal layer comprises openings at locations of the main emission surfaces of the layer stacks 11. This reduces the amount of light coming from the light source being reflected on the substrate 20 or the active region stacks 11 towards the multicore fibre thus preventing excitation light from being fed into the optical fibres.

Although only a single light source 30 is illustrated herein, one will note to implement a plurality of such light sources within the dielectric transparent material 19a. Moreover, the light source 30 may comprise an optoelectronic component with its active region arranged substantially perpendicular to the respective active regions of the semiconductor layer stacks 11. In some aspects, for example, such light sources can be located between two adjacent optoelectronic components 11 and completely embedded into the transparent material 19a.

In a further embodiment, the light source 30 can be implemented by a large optoelectronic device arranged substantially in parallel over the plurality of main emission surfaces of the layer stacks 11. Such approach has several benefits. For example, the arrangement could be implemented as a monolithic component including the plurality of optoelectronic components 10 as well as the light source 30. If implemented as an independent element, light source 30 can be optimized and attached by an adhesive or bonded onto the surface of the layer stacks of the plurality of optoelectronic components. Moreover, an optoelectronic component as a light source 30 with a substantially larger lateral dimension can cover the main emission surface of the optoelectronic components and of the layer stacks 11 thus providing a substantially equally distributed light towards the active regions of layer stacks 11.

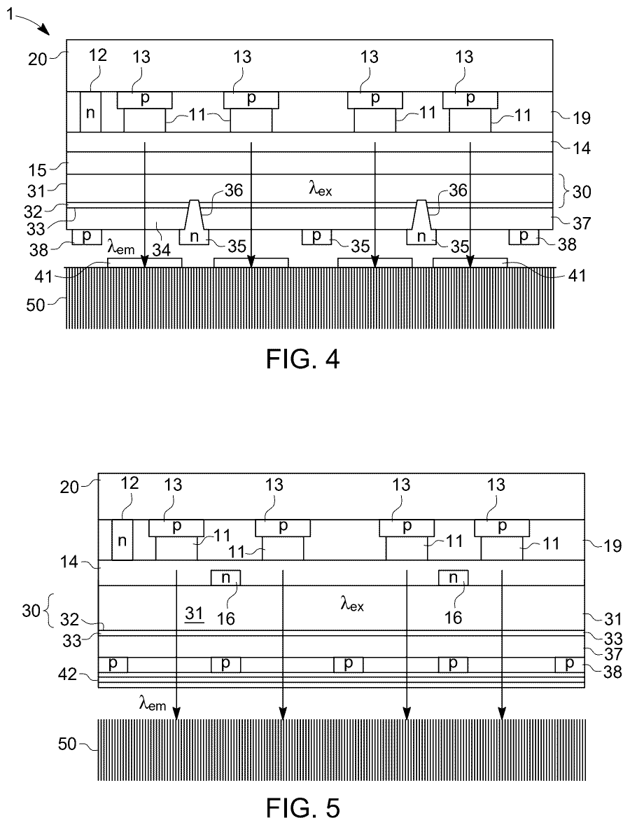

FIG. 4 illustrates an embodiment, in which the light source 30 is implemented as a semiconductor layer stack for providing the excitation light with the excitation wavelength. The layer stack of light source 30 comprises a first doped layer 31, a second doped layer 33 as well as an active region 32 arranged between the first doped layer 31 and the second doped layer 33.

The material of the light source is based on Gan with the active region comprising InGaN to shift the excitation wavelength towards the red portion of the spectrum. This is because the material for the layer stack 11 is GaAs/AlGaAs which emits in the red portion of the spectrum. Due to the attachment with the adhesive layer 15, one can optimize the layer stack individually and separately from each other.

The first doped layer 31 is an n-doped layer in this particular example, which is connected by a plurality of metallic or highly conductive feed-through via 35. The feed-through via 35 are located in openings through the active region 32, the p-doped layer 33 and the transparent p-contact layer 37. The via 35 are insulated with a dielectric material 36 to prevent a short circuit between the n-contacts 35 and the p-contact material 37.

A plurality of p-contacts 38 outside the area of the main emission surfaces of layer stack 11 are located on the transparent p-contact material 37. The layer stack of the light source 30 is then attached to the common transparent n-contact layer 14 of the plurality of optoelectronic components using an adhesive transparent material 15. The common n-contact layer 14 is roughened to improve the out-coupling of the photoluminescent light towards the multicore fibre optics 50 and the in-coupling of the excitation light. In addition, the p-contact material 37 is transparent for the photoluminescence of light and can also be roughened to provide a better coupling the towards the multicore optical fibres 50.

Finally, a plurality of filter elements 41 are located on the multicore optical fibres 50 opposite the main emission surfaces of the layer stacks 11. The filter elements 41 are transparent for the photoluminescent light but reflective for light from the light source 30. The step of attaching the layer stack of the light source 32 to the optoelectronic components can be conducted on a chip to chip, chip to wafer or wafer to wafer level. Furthermore, the structure as depicted herein in FIG. 4 for the layer stack of the light source 30 can be reused from existing architectures with transparent p-contacts including a transparent conductive oxide.

The light source in the embodiment of FIG. 4 is manufactured separately and subsequently attached to the plurality of optoelectronic components on substrate 20 using adhesive layer 15. However, depending on the material used for the optoelectronic components 10 as well as for light source 30, the arrangement is implemented as a monolithic wafer structure. In such instance, the plurality of optoelectronic components as well as the layer stack of light source 30 comprise a common n-contact material 14 arranged between the layer stack 30 and the plurality of optoelectronic components.

The common n-contact material 14 is electrically connected to an n-contact 12 through the insulating layer 19. Furthermore, a couple of metal contact traces 16 are arranged between two adjacent optoelectronic components for distributing the current through the common n-contact, thereby providing a substantial equally distributed current injection into the layer stack 30 as well as providing an equal potential to the layer stack 11 of the optoelectronic components 10.

On the opposite side of the layer stacks of the light sources, the transparent conductive layer 37 is attached, on which a plurality of metal contact traces 38 are arranged upon. Furthermore, a distributed Bragg reflector, DBR is applied to the transparent p-contact layer 37 and the contacts 38 for reflecting excitation light towards the layer stacks 11. BPR mirror material 42 comprises several insulating transparent layers having different refractive indices, which are transparent for the photoluminescent light by the optoelectronic components 10 but reflective for the excitation light from light source 30.

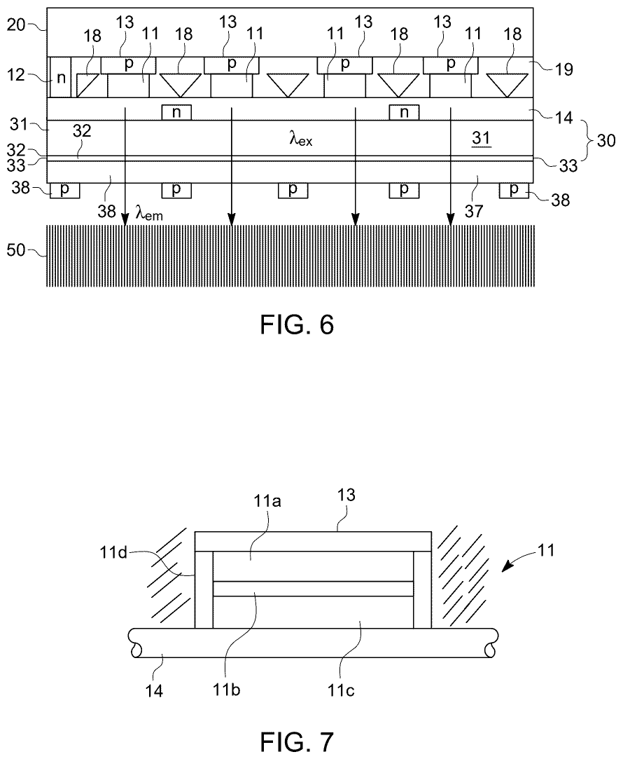

In another aspect illustrated in FIG. 6, a plurality of reflective elements, for example in form of triangles or pyramids are implemented in the dielectric transparent layer material 19. The sidewalls of the reflecting elements 18 are inclined such that excitation light from the layer stack of the light source 30 is reflected towards of the active region of layer stacks 11 of the optoelectronic components 10. The reflection of such excitation light will further improve the efficiency for generating the photoluminescent light, thereby reducing the wasted light from light source 30.

Similar to the previous embodiments, the structures can be implemented either as separate elements including the substrate 20 with a plurality of optoelectronic components and layer stacks 11 deposited thereupon and the light source 30. Alternatively, both elements can be manufactured together as a monolithic integrated circuit.

Layer stacks 11 of the plurality of optoelectronic components are optimized for absorbing excitation light in order to improve the overall quantum efficiency, but not necessarily optimized for carrier injection into the active region. This is due to the lack of requirements for carrier injection when the optoelectronic component is biased in the forward direction. Rather, the active region should be optimized for carrier separation when a reverse biased is applied.

FIG. 7 illustrates an embodiment of layer stack 11 of an optoelectronic component 10. Layer stack 11 comprises a first doped layer 11c, the second doped layer 11a as well as the active region 11b arranged in between. The doping concentration of layers 11a and 11c can be adapted to either block generated charge carriers from diffusing into doped layers or prevent dopant diffusion from doped layers 11a and 11c into the active region 11b. The layer stack 11 also comprises a mesa-etched structure with a re-grown insulating layer 11 be applied on the mesa facets. This reduces the number of non-radiative recombination centres at the mesa facets thereby improving the radiative recombination and the generation of photoluminescent light during operation.

In this regard, doped layer 11c can further comprise a roughened or otherwise structured surface to improve the light absorption of the excitation light into active region 11b. In this regard, the bandgaps of doped layers 11a and 11c are adjusted that no absorption of excitation light takes place in the doped layers, but substantially in the active region 11b in between. Two contacts 13 and 14 are further provided on the different sides of the layer stack. While layer 14 comprises a transparent conductive oxide to be used as a common contact layer, contact 13, for example including a metal contact area covers the doped layer 11a. This allows to individually address a plurality of layer stacks 11 arranged adjacent to each other on a common substrate. The layer stacks can be embedded in a dielectric transparent material, for stability purposes but also for light guiding purposes in cases the excitation light is fed parallel to layer 14.

1.-19. (canceled)

20. An optoelectronic arrangement comprising:
a plurality of optoelectronic components, each having a main emission surface that is attachable to one or more optical fibres, wherein each of the plurality of optoelectronic components comprises a semiconductor layer stack, and wherein each semiconductor layer stack comprises a first layer having a first doping type, a second layer having a second doping type different from the first doping type and an active region arranged in between the first and second layer, the active region configured to emit light of a first wavelength;
a light source configured to emit light of a second wavelength, the second wavelength being shorter than the first wavelength,
wherein the light source is configured to illuminate the active regions of each semiconductor layer stack to generate, by the active regions of each semiconductor layer stack, photoluminescent light, the photoluminescent light being emitted at least partially through the main emission surface, and
wherein the optoelectronic arrangement is configured to modulate a generation of the photoluminescent light by individually supplying a voltage and/or current signal to the semiconductor layer stack of the plurality of optoelectronic components.

21. The optoelectronic arrangement according to claim 20, further comprising a control circuit configured to provide pulse or amplitude modulated reverse voltage signals to the plurality of optoelectronic components.

22. The optoelectronic arrangement according to claim 20,
wherein the plurality of optoelectronic components is attached to a common substrate, and
wherein the common substrate comprises a control circuit configured to provide the voltage and/or current signal to individually supply the semiconductor layer stacks of the plurality of optoelectronic components.

23. The optoelectronic arrangement according to claim 20, wherein the plurality of optoelectronic components comprises at least one of:
a common contact plane comprising the main emission surfaces of the plurality of optoelectronic components;
a first reflector configured to reflect light of the first wavelength towards the main emission surface; or
a second reflector configured to reflect light of the second wavelength towards the active region.

24. The optoelectronic arrangement according to claim 20,
wherein the semiconductor layer stacks of the plurality of optoelectronic components are embedded in a common insulation layer material, and
wherein optionally the common insulation layer material is at least partially transparent for the second wavelength.

25. The optoelectronic arrangement according to claim 20, further comprising:
one or more reflective elements arranged in between two adjacent semiconductor layer stacks of the plurality of optoelectronic components within a common insulation layer material,
wherein the one or more reflective elements are configured to redirect light of the second wavelength towards the semiconductor layer stack and/or redirect light of the first wavelength towards the optical fibres.

26. The optoelectronic arrangement according to claim 20, wherein each active region comprises at least one of one of:
a quantum well structure, optionally with one or more doped quantum well layers and/or with one or more doped barrier layers;
a multi-quantum well structure, optionally with one or more doped quantum well layers and/or with one or more doped barrier layers;
a plurality of quantum dots; or
a mesa etched structure, wherein an active region material comprises a larger bandgap adjacent to a perimeter of the active region.

27. The optoelectronic arrangement according to claim 20, wherein the light source comprises at least two optoelectronic devices configured to illuminate the active region of the plurality of optoelectronic components from different locations and/or different directions.

28. The optoelectronic arrangement according to claim 20, further comprising a filter arranged downstream of a beam path of the main emission surface of the plurality of optoelectronic components, or arranged in front of one or more optical fibres, wherein the filter is transparent for light of the first wavelength and reflective or absorbent for light of the second wavelength, and wherein optionally the filter comprises a DBR structure.

29. The optoelectronic arrangement according to claim 20, wherein the light source comprises a semiconductor layer stack having an active region arranged between the plurality of optoelectronic components and the one or more optical fibres, and wherein optionally a wavelength selective filter is arranged between the active region of the semiconductor layer stack of the light source and the one or more optical fibres.

30. The optoelectronic arrangement according to claim 20, wherein the light source comprises a semiconductor layer stack having an active region covering one or more of the optoelectronic components and further comprising at least one of:
an adhesive layer between the semiconductor layer stack and the plurality of optoelectronic components; and
a common contact layer between the semiconductor layer stack and the plurality of optoelectronic components.

31. The optoelectronic arrangement according to claim 29, wherein the semiconductor layer stack of the light source and each semiconductor layer stack of the plurality of optoelectronic components share a common contact plane, and wherein optional the common contact plane comprises a conductive transparent material.

32. The optoelectronic arrangement according to claim 29, wherein the semiconductor layer stack of the light source comprises an active region including at least one of:
a quantum well structure; or
a multi-quantum well structure.

33. The optoelectronic arrangement according to claim 20,
wherein a material of the semiconductor layer stack of the plurality of optoelectronic components comprises one of GaAs, AlGaAs, InAlGaAs and InGaAsSb or combinations thereof; and/or
wherein a material of the light source comprises one of GaN, AlGaN, InAlGaN, GaP, AlP, AlGaP or InGaAlP.

34. A method for operating one or more optoelectronic components, wherein the one or more optoelectronic components are attached to one or more optical fibres, wherein the one or more optoelectronic components configured to be supplied individually by a voltage and/or current signal, and wherein the one or more optoelectronic components comprise a semiconductor layer stack with an active region configured to emit light of a first wavelength, the method comprising:
illuminating active regions of layer stacks of the one or more optoelectronic components with light of a second wavelength, the second wavelength being shorter than the first wavelength;
generating photoluminescence in the active regions of the layer stacks in response to illuminating, wherein at least a portion of photoluminescent light is directed to one or more optical fibres;
applying a modulated electrical field in a reverse bias at the active regions of the layer stacks; and
coupling portions of modulated photoluminescent light into the one or more optical fibres.

35. The method according to claim 34, wherein illuminating the active regions comprises the illuminating the active regions of the layer stacks from different locations and/or different directions.

36. The method according to claim 34, wherein applying the modulated electrical field comprises modulating photoluminescence in a respective active region by individually applying a reversely biased voltage and/or current signal to the one or more optoelectronic components.

37. The method according to claim 34, further comprising suppressing, by absorbing or reflecting, light of the second wavelength in a beam path of the one or more optical fibres.

38. The method according to claim 34, wherein a rise and fall time of a reversed biased voltage an/or current signal is in a range between 10 ps and 100 ps.
